(19) United States
(12) Patent Application Publication
(10) Pub. No.: US 2026/0367124 A1
(43) Pub. Date: Nov. 19, 2026

(54) Method for Variance-Based Jitter Analysis and Measurement in Multi-Level PAM Eye Diagrams Using Finite Mixture Models

(71) Applicant: Donghong Wu, Union City, CA (US)

(72) Inventor: Donghong Wu, Union City, CA (US)

(21) Appl. No.: 19/209,806

(22) Filed: May 16, 2025

(51) Int. Cl. G01R 29/027; G06T 11/10; G06T 11/60

(52) U.S. Cl. CPC G01R 29/027; G06T 11/10; G06T 11/60; G06T 2210/22

(57) ABSTRACT

A method is disclosed for variance-based jitter analysis and measurement in high-speed serial communication systems using multi-level Pulse Amplitude Modulation (PAM-n) eye diagrams. The invention redefines jitter as statistical variance, extending analysis beyond the time domain into the amplitude domain. The method includes editing the PAM-n eye diagram into a one-unit interval (1UI) pattern, selecting level groups, and acquiring a horizontal lane histogram to establish a reference mean and standard deviation, along with a level histogram for jitter decomposition. A Gaussian Mixture Model (GMM) with Expectation-Maximization (EM) is used to decompose the level histogram. A Finite Mixture Model (FMM) computes variance-based jitter components: deterministic jitter (DJ), random jitter (RJ), and total jitter (TJ). Additional metric parameters, including grand mean shift, DJ mean shift, unweighted RMS sigma, and delta RMS sigma, enhance precision relative to a fixed reference. This variance-based framework enables robust jitter analysis across diverse PAM-n systems.

### CROSS-REFERENCE TO RELATED APPLICATIONS

This application is a continuation-in-part of U.S. patent application Ser. No. 18/146,876, filed on Dec. 27, 2022, which is currently pending and allowed. This application also claims the benefit of U.S. Provisional Patent Application No. 63/723,114, filed on Nov. 20, 2024, under 35 U.S.C. § 119(e). The entire contents of both applications are incorporated herein by reference.

### FIELD OF THE INVENTION

The present invention relates to digital communication systems, specifically to the method for jitter analysis and measurement in multi-level Pulse Amplitude Modulation (PAM-N) signal patterns in high-speed serial communication systems.

### BACKGROUND OF THE INVENTION

In modern digital communication systems, a digital sampling oscilloscope captures discrete-time representations of analog waveforms at precisely defined intervals. This time-domain sampling enables the construction of system-specific signal patterns for analysis and visualization. For example, multi-level Pulse Amplitude Modulation (PAM-n) eye diagrams are commonly generated in high-speed serial communication systems to evaluate signal quality. Jitter analysis and characterization of these eye patterns are critical to assessing overall system integrity, as jitter can degrade signal fidelity, increase bit error rates, and compromise performance and reliability. Accurate jitter analysis is therefore essential for optimizing link performance, ensuring compliance with industry standards, and facilitating effective debugging and validation processes.

Jitter in an eye diagram is defined as the temporal deviation of a data-bit event from its ideal timing position. This time-domain interpretation of jitter is commonly applied to analyze timing variations at the signal crossings, typically at the intersections of rising and falling edges along the horizontal time axis (x-axis), in binary modulation schemes such as non-return-to-zero (NRZ) or PAM2 eye diagrams. However, the traditional time-domain approach is inadequate for PAM-n signaling, which presents a more complex structure characterized by multiple amplitude levels and a greater number of transition lanes with overlapping timing distributions. This complexity is illustrated by the label 11 in FIG. 1. Conventional jitter decomposition methods, including the Dual-Dirac model and tail-fitting algorithms, often fail to deliver analysis results when applied to PAM-n eye diagrams, particularly due to the increased number of crossing points and the presence of inter-symbol dependencies that obscure individual transition characteristics.

U.S. patent application Ser. No. 18/146,876, filed on Dec. 27, 2022, and titled “Jitter Measurement of the Multi-level PAM Eye Diagram,” discloses a method for measuring jitter in PAM-n signals. That approach interpreted jitter as variance in statistics and leveraged one-way analysis of variance (ANOVA) to evaluate jitter in mixed-lane regions of a PAM-n eye diagram by quantifying signal dispersion via histogram analysis. The method involved importing a PAM-n eye diagram, editing it to extract a one-unit interval (1UI) pattern, and analyzing histograms from both horizontal lanes (hlane) and transition-lane mixtures (level signals) within selected level groups. Gaussian fitting was used to extract jitter parameters. In that method, random jitter (RJ) was assessed through the spread of the level histogram, while deterministic jitter (DJ) was derived from the mean shift relative to the hlane baseline. Total jitter (TJ) was computed as the sum of RJ and DJ, providing a structured framework for PAM-n jitter assessment.

However, the previously disclosed invention did not address key aspects critical for robust jitter characterization. In particular, it lacked a systematic framework for decomposing the level histogram into its component distributions using statistical mixture models. Additionally, it did not provide explicit mathematical expressions for calculating DJ and RJ based on mixture parameters. The approach also omitted analysis of several important jitter metrics related to DJ and RJ, such as grand mean shift, DJ mean shift, and root-mean-square (RMS) sigma increment, thereby limiting its ability to deliver a complete and detailed characterization of jitter components on PAM-n pattern.

### SUMMARY OF THE INVENTION

The present invention introduces a statistical model that defines jitter in terms of statistical variance and establishes a variance-based framework for analyzing and measuring jitter in multi-level Pulse Amplitude Modulation (PAM-n) signal patterns. This variance-based approach provides several advantages in simplifying the partitioning of a PAM-n eye diagram for jitter analysis. By shifting the analytical perspective from the conventional time-domain to the amplitude-domain, the method enables consistent segmentation of the eye diagram into distinct level groups along the signal amplitude axis. Each level group includes a horizontal lane (hlane) and its associated inter-level transition lanes, together forming a structured level histogram. As illustrated by the label 21 in FIG. 1, this approach facilitates uniform histogram acquisition across various PAM-n levels, reduces background noise complexity, and enables standardized processing for statistical jitter decomposition. This structured and repeatable segmentation significantly improves the robustness, precision, and scalability of jitter characterization in multi-level signaling systems.

The proposed model performs statistical decomposition of PAM-n level histograms using a Gaussian Mixture Model (GMM) in combination with the Expectation-Maximization (EM) algorithm, enabling extraction of key distribution parameters for each subcomponent. Based on this decomposition, the model applies a Finite Mixture Model (FMM) framework to compute variance-based jitter components, including deterministic jitter (DJ), random jitter (RJ), and total jitter (TJ). To ensure consistent and reproducible analysis, the model designates the horizontal lane (hlane) within each level histogram as a stable, noise-resistant reference point. By establishing the horizontal lane mean as the reference point, the model creates a stable and physically significant foundation for absolute jitter measurement and analysis. With the introduction of novel jitter metric parameters, this strategy enhances measurement precision, reduces sensitivity to model fitting errors, and improves repeatability in characterizing jitter behavior under varying signal conditions and across different PAM-n eye diagram profiles.

### BRIEF DESCRIPTION OF DRAWINGS

FIG. 1 illustrates a conceptual comparison between conventional jitter analysis using horizontal (x-axis) sampling and the proposed variance-based jitter analysis using vertical (y-axis) sampling in a PAM3 eye diagram.

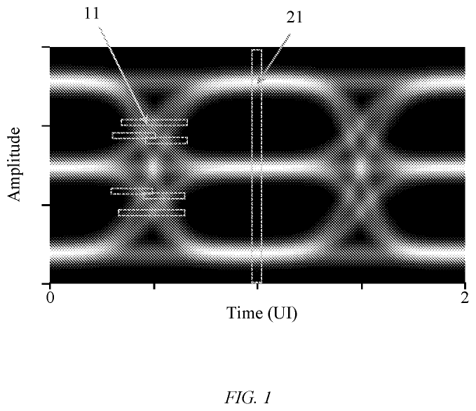

FIG. 2 is a main flowchart illustrating an example method for variance-based jitter analysis and measurement in PAM-n eye diagrams using finite mixture models (FMM).

FIG. 3 is a flowchart illustrating an example method for editing a PAM-n eye diagram to generate a 1UI PAM-n pattern.

FIG. 4 illustrates the selection of sampling points on a PAM4 eye diagram for creating a 1UI pattern image, based on symmetrical local patterns and center alignment.

FIG. 5 is a flowchart illustrating an example method for grouping transition lanes into level groups and configuring a jitter testing sequence within a 1UI PAM-n pattern.

FIG. 6 illustrates the formation of distinct level groups and the labeling of transition lanes according to their Start and End states within a 1UI PAM4 pattern.

FIG. 7 is a flowchart illustrating an example method for acquiring horizontal lane (hlane) and level histograms from designated sampling points within a level group.

FIG. 8 illustrates the selection of sampling points for acquiring a hlane histogram at the midpoint of a level and a level histogram near the end of the level region within a 1UI PAM4 pattern.

FIG. 9 is a flowchart illustrating an example method for decomposing a level histogram using a Gaussian Mixture Model (GMM) and Expectation-Maximization (EM) algorithm.

FIG. 10 illustrates the GMM mode selection process using the Akaike Information Criterion (AIC) and the Bayesian Information Criterion (BIC) to determine the optimal number of decomposition components for the level histogram labeled 424 in the PAM4 pattern shown in FIG. 8.

FIG. 11 illustrates the visualization and reporting of GMM parameters and jitter metrics, including deterministic jitter (DJ), random jitter (RJ), total jitter (TJ), and associated metric parameters for the level histogram labeled 424 in the PAM4 pattern shown in FIG. 8.

### DETAILED DESCRIPTION OF THE INVENTION

Embodiments of methods for variance-based jitter analysis and measurement in multi-level PAM-n eye diagrams are described herein. In the following description, specific details are provided to facilitate a comprehensive understanding of the disclosed embodiments. However, it will be apparent to those skilled in the art that the invention may be practiced without some of these specific details. The particular models, statistical algorithms, and logical process flows disclosed herein may be implemented individually or in combination, and may be adapted or modified to suit various application contexts without departing from the scope of the invention.

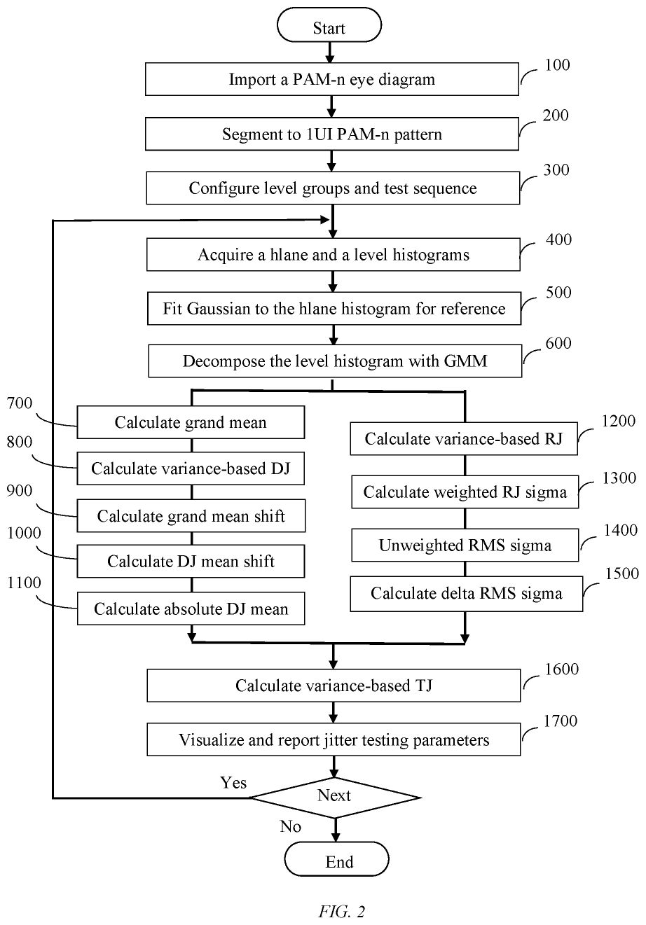

FIG. 2 is a main flowchart illustrating an example method for variance-based jitter analysis and measurement in PAM-n eye diagrams using finite mixture models (FMM). The flowchart provides a top-level overview of the entire process, including editing the eye diagram, configuring level groups, acquiring histograms, performing GMM decomposition, and calculating jitter metrics. A sequence of steps in the method comprising: importing a PAM-n eye diagram (Step 100); editing the diagram to form a one-Unit-Interval (1UI) PAM-n pattern (Step 200); identifying and configuring level groups and a jitter testing sequence (Step 300); acquiring histograms for the horizontal lane and level region (Step 400); fitting a reference Gaussian model to the horizontal lane histogram (Step 500); decomposing the level histogram using a Gaussian Mixture Model (GMM) and Expectation-Maximization (EM) algorithm (Step 600); and computing variance-based deterministic jitter (DJ), random jitter (RJ), and total jitter (TJ) metrics using Finite Mixture Model (FMM) equations (Steps 700-1600). The method concludes by visualizing and reporting jitter parameters and statistical decomposition results (Step 1700).

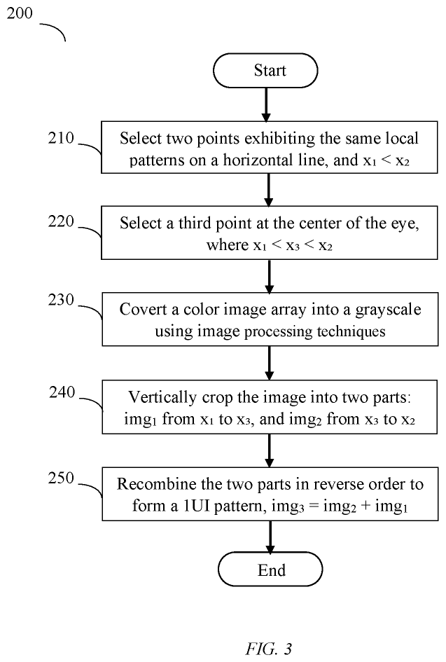

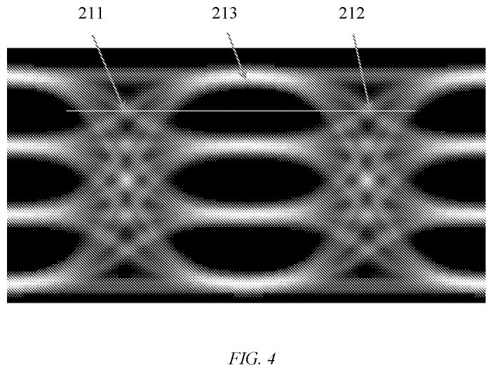

FIG. 3 is a flowchart illustrating an example method for editing a PAM-n eye diagram to generate a 1UI PAM-n pattern. The process comprises selecting two sampling points, denoted (x₁, y₁) and (x₂, y₂), along a horizontal line within the eye diagram where the local pattern is visually similar, with x₁<x₂ (Step 210). A third point (x₃, y₃) is selected at the center of the eye diagram such that x₁<x₃<x₂ (Step 220). The original color image is converted into a grayscale image using image processing techniques, such as channel averaging or luminance extraction (Step 230). The grayscale image is vertically cropped into two segments: a first segment (img₁) extending from x₁ to x₃, and a second segment (img₂) from x₃ to x₂ (Step 240). These two segments are recombined in reverse order (img₃=img₂+img₁) to generate a temporally aligned and symmetrical 1UI PAM-n pattern suitable for histogram sampling and analysis (Step 250). The sampling points are further labeled as 211 for (x₁, y₁), 212 for (x₂, y₂), and 213 for (x₃, y₃) in FIG. 4.

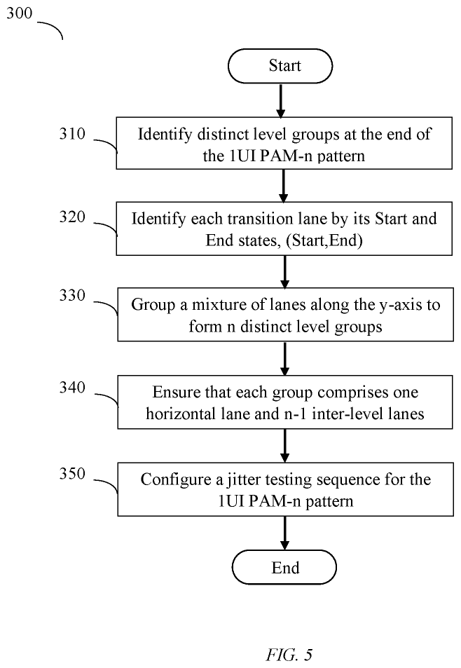

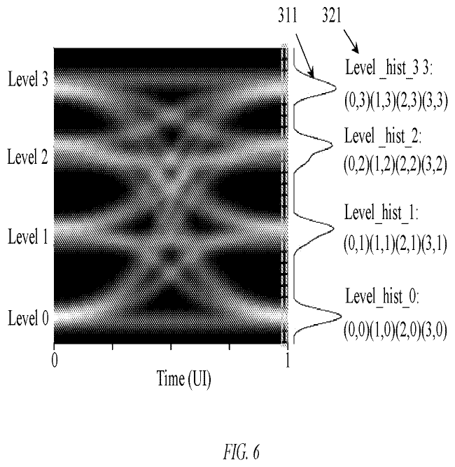

FIG. 5 is a flowchart illustrating an example method for grouping transition lanes into level groups and configuring a jitter testing sequence within a 1UI PAM-n pattern. The process involves identifying distinct amplitude levels at the end of the 1UI PAM-n pattern (Step 310). Each transition lane is labeled by its initial and terminal states, denoted as (Start, End) (Step 320). These lanes are grouped along the vertical (amplitude) axis to form n level groups, corresponding to the n distinct signal levels in the PAM-n modulation scheme (Step 330). Each level group consists of one horizontal lane (hlane), representing the steady-state level, and (n−1) inter-level transition lanes that share a common Start or End state (Step 340). A jitter testing sequence is then configured to test these level groups in a defined order (e.g., top-down or bottom-up), focusing on the most central or representative groups for efficient jitter estimation (Step 350). The formation of distinct level groups and the labeling of transition lanes by their Start and End states are further illustrated in FIG. 6, with reference numerals 311 and 321, respectively.

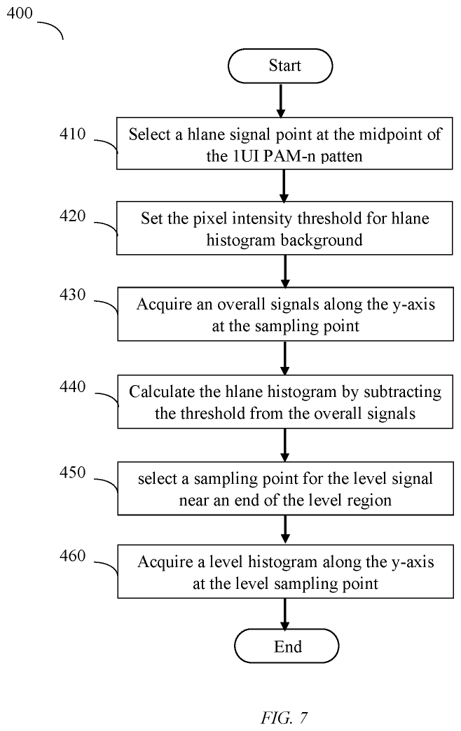

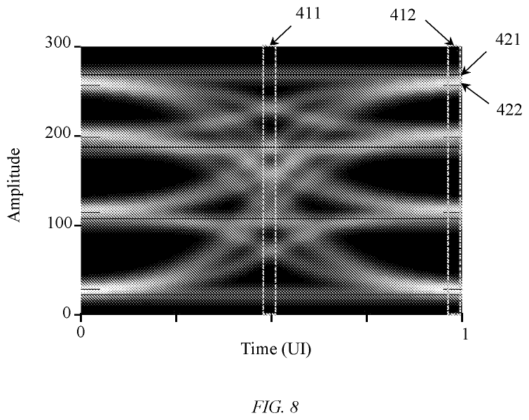

FIG. 7 is a flowchart illustrating an example method for acquiring horizontal lane (hlane) and level histograms from designated sampling points within a level group. The process comprises selecting two vertical sampling points for each level group. The hlane sampling point is selected at the midpoint of the horizontal segment of the level (Step 410). At each sampling point, vertical (y-axis) pixel intensities are aggregated. For the hlane histogram, a pixel intensity threshold is applied (Step 420) to subtract background noise and isolate meaningful signal content (Step 430). The resulting vertical profile constitutes the hlane histogram (Step 440). For the level histogram, a separate sampling point is selected near the end of the transition region (Step 450), and the full signal intensities are collected along the vertical axis at this designated endpoint (Step 460). The hlane histogram serves as a critical input for reference Gaussian fitting, while the level histogram represents the primary dataset for jitter decomposition and measurement. The sampling areas used to acquire the hlane and level histograms are further identified in FIG. 8 as reference numerals 411 and 412, respectively. The expected mean positions of the hlane and level histograms are denoted as 421 and 422.

The step 500 in FIG. 2, following the acquisition of the hlane and level histograms, involves fitting a Gaussian distribution to the hlane histogram to obtain a reference mean (μ_{ref}) and a reference standard deviation (σ_{ref}). These reference parameters serve as baselines for absolute jitter analysis, representing the nominal timing center and signal spread of the steady-state portion of the level. The fitting may be performed using either least-squares optimization or maximum likelihood estimation. The resulting parameters are later used as baselines for comparison with GMM-derived metrics of the level histogram, including the grand mean shift, DJ mean shift, absolute DJ mean, mixture-based RJ sigma, and RMS sigma increment. This step ensures that jitter metrics are referenced to a stable and statistically justified signal anchor point for performing absolute jitter analysis and measurement of a level histogram within a 1UI PAM-n pattern.

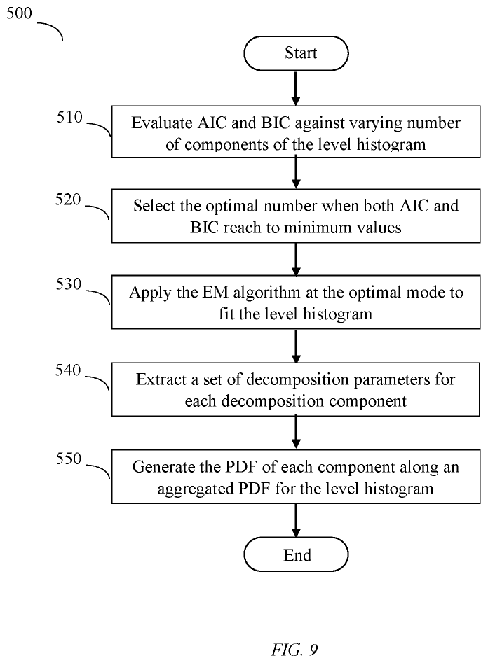

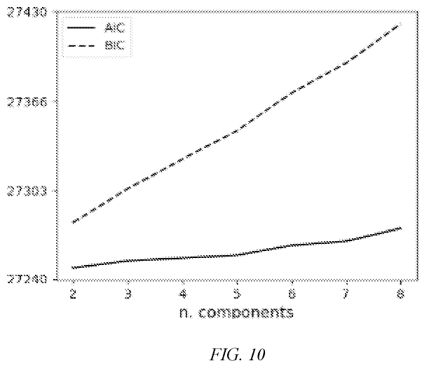

FIG. 9 is a flowchart illustrating an example method for decomposing a level histogram using a Gaussian Mixture Model (GMM) and Expectation-Maximization (EM) algorithm. The method involves a machine learning technique, namely, GMM in conjunction with EM to estimate the parameters of each Gaussian component in a mixture distribution. To determine the optimal number of components for the model, the method begins by evaluating the Akaike Information Criterion (AIC) and the Bayesian Information Criterion (BIC) over a predefined range of candidate models (Step 510). The optimal component count is then selected at the point where both the AIC and BIC values reach or closely approximate their respective minimums (Step 520). This step is visually represented in FIG. 10, which displays curves of the AIC and BIC scores plotted against the number of decomposition components in the level histogram. Once the optimal model complexity is established, the EM algorithm is applied to fit the level histogram to the selected number of Gaussian components (Step 530). This process yields a set of decomposition parameters for each component, including the mixing weight (wᵢ), mean (μᵢ), and standard deviation (σᵢ) (Step 540). These parameters define the characteristics of the individual Gaussian distributions and serve as the statistical basis for subsequent variance-based jitter analysis. The method generates individual probability density functions (PDFs) for each component, as well as an aggregate PDF that represents the full level histogram. This statistical decomposition forms the foundation for computing key jitter metrics, including variance-based deterministic jitter (DJ) and random jitter (RJ) components (Step 550).

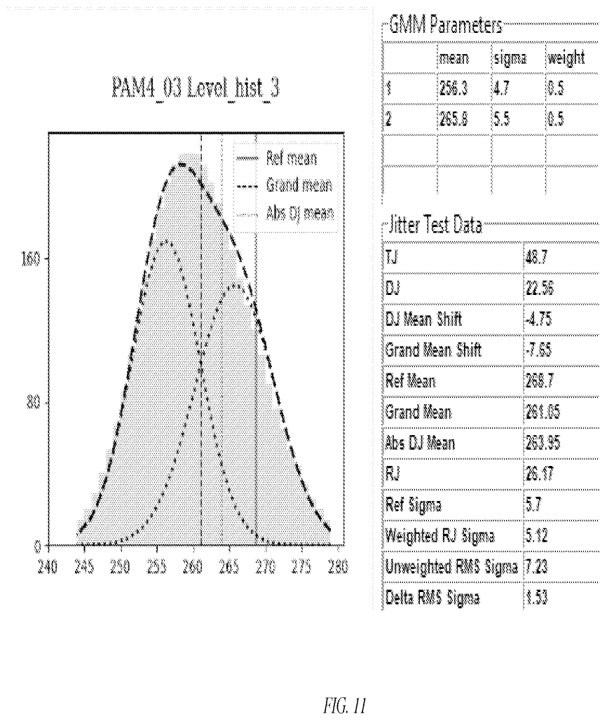

FIG. 11 illustrates the visualization and reporting of GMM parameters and jitter metrics, including deterministic jitter (DJ), random jitter (RJ), total jitter (TJ), and associated metric parameters. The step concludes with the visualization and reporting of the extracted statistical and jitter-related parameters to support interpretation, validation, and documentation. Specifically, this step involves presenting the Gaussian Mixture Model (GMM) component parameters, including mixing weights, means, and standard deviations, alongside the computed jitter metrics, such as variance-based deterministic jitter (DJ), random jitter (RJ), and total jitter (TJ), as well as all associated sub-metrics (e.g., grand mean shift, RMS sigma increment, and absolute DJ mean).

The results may be displayed in various formats to enhance analytical clarity. These include graphical plots, such as overlaid probability density functions (PDFs) for each GMM component and their aggregate, as well as jitter band visualizations that illustrate the distribution and boundaries of signal variation. Additionally, tabulated data outputs may be generated to summarize numerical values for all decomposition parameters and jitter metrics across different level groups. This final step facilitates comprehensive evaluation of the signal integrity in PAM-n systems and supports both comparative studies and formal reporting.

### Variance-Based Jitter and Metric Calculations Using Finite Mixture Model (FMM) Framework

### Finite Mixture Model (FMM)

A finite mixture model (FMM) is a probabilistic model that represents a population as a mixture of a finite number of component distributions. The probability density function (PDF) of a one-dimension FMM with k Gaussian components is:

$$f ( x ) = {\sum }_{i = 1}^{k} {ω}_{i} N ( x ; {μ}_{i} , {σ}_{i}^{2} )$$

where:
ƒ(x) is the mixture density function
ωᵢ is the mixing weight of the i-th component, satisfying

$${\sum }_{i = 1}^{k} {ω}_{i} = land 0 \leq {ω}_{i} \leq 1 ;$$

μᵢ and σᵢ are the mean and standard deviation (one-sigma) of the i-th Gaussian component, respectively;

$$N ( x ; {μ}_{i} , {σ}_{i}^{2} )$$

denotes a normal distribution with mean μᵢ and variance

$${σ}_{i}^{2} ;$$

k ranges from 1 to K.

Claims 6-14 are directed to a variance-based jitter analysis and measurement method employing a finite mixture model (FMM). The following definitions and mathematical formulations apply:

### Key Moments:

1. Mixture Mean (Grand Mean):

μ_{g}=Σωᵢμᵢ
2. Mixture Variance (Total Variance Decomposition):

$${σ}_{tot}^{2} = \sum {ω}_{i} {σ}_{i}^{2} + \sum {{ω}_{i} ( {μ}_{i} - {μ}_{g} )}^{2} = {σ}_{within}^{2} + {σ}_{between}^{2}$$

Where:

$${σ}_{within}^{2} = \sum {ω}_{i} {σ}_{i}^{2}$$

is the weighted average of component variances;

$${σ}_{between}^{2} = \sum {{ω}_{i} ( {μ}_{i} - {μ}_{g} )}^{2}$$

is the weighted variance of component means.

### Grand Mean Calculation (Claim 6)

The grand mean (μ_{g}) is calculated to represent the central tendency of the entire decomposed level histogram. It is computed as a weighted average of the component means:

$${μ}_{g} = {\sum }_{i = 1}^{k} {ω}_{i} {μ}_{i}$$

Where k is the optimal component number derived from Claim 5. The grand mean serves as the statistical center of a level histogram for evaluating deterministic jitter.

### Variance-Based Deterministic Jitter Calculation (Claim 7)

The variance-based Deterministic Jitter (DJ) is defined as

$${σ}_{between}^{2}$$

in mixture variance, which quantifies systematic deviations of component means. It is calculated as a weighted variance of the component means with respect to the grand mean:

$$DJ = {\sum }_{i = 1}^{k} {{ω}_{i} ( {μ}_{i} - {μ}_{g} )}^{2}$$

This formulation represents the signal shifts due to deterministic effects such as inter-symbol interference (ISI) or imperfect signal levels.

### DJ Metric—Grand Mean Shift Calculation (Claim 8)

The grand mean shift (Δ_{g}) is a derived metric defined as the difference between the grand mean (μ_{g}) and the reference mean (μ_{ref}) established from the hlane histogram:

Δ_{g}=μ_{g}−μ_{ref}

This metric reflects the global displacement of the level histogram relative to the reference mean.

### DJ Metric—DJ Mean Shift Calculation (Claim 9)

The DJ mean shift (Δ_{d}) is defined as the square root of the variance-based DJ value, providing a standard deviation-like interpretation of variance-based deterministic jitter:

Δ_{dj}=±\sqrt{DJ}

The DJ mean shift Δ_{dj}, expressed in RMS units, enables direct comparison with the grand mean shift Δ_{g}. While the grand mean shift is typically smaller due to cancellation of symmetrically distributed component means, the DJ mean shift reflects the total spread by summing squared deviations, thus avoiding cancellation. This distinction is especially evident in the middle levels of a PAM-n eye diagram, where symmetric transitions can suppress the grand mean shift but still yield a significant DJ mean shift.

### DJ Metric—Absolute DJ Mean Calculation (Claim 10)

The absolute DJ mean is defined as a directionally corrected estimate of the most probable position of the level cluster for deterministic jitter analysis. It is computed using the following equation:

μ_{abs}=μ_{ref}+sign(Δ_{g})|Δ_{dj}|

### Where:

μ_{ref} is the reference mean from the hlane histogram;
sign(Δ_{g}) indicates the direction of the grand mean shift, with Δ_{g}=μ_{g}−μ_{ref};
   |Δ_{dj}| is the absolute value of the DJ mean shift.
   This formulation ensures that the deterministic jitter displacement is added to the reference mean in the correct direction, based on the sign of the grand mean shift. By using the magnitude of the DJ mean shift, the method guarantees a consistent and non-negative contribution, while maintaining directional alignment. The absolute DJ mean is particularly useful for visually marking and comparing the relative positions of the reference mean, grand mean, and DJ-induced shift on a level histogram, enhancing both interpretability and reporting precision.

### Variance-Based Random Jitter Calculation (Claim 11)

The variance-based Random Jitter (RJ) is defined as

$${σ}_{within}^{2}$$

in mixture variance, which accounts for variance caused by random noise and other stochastic processes. It is calculated as a weighted average of variances from the Gaussian components in a level histogram:

$$RJ = {\sum }_{i = 1}^{k} {ω}_{i} {σ}_{i}^{2}$$

The RJ value remains robust even in the presence of symmetric or offsetting component distributions, because variances are always non-negative and do not cancel out.

### RJ Metric—Weighted RJ Sigma Calculation (Claim 12)

The weighted RJ sigma (σᵣⱼ) is the square root of the variance-based RJ value, providing a weighted RJ value in terms of standard deviation. It is computed as:

$${σ}_{rj} = \sqrt{RJ} = \sqrt{\sum {ω}_{i} {σ}_{i}^{2}}$$

The weighted RJ sigma can be used for a relative RJ measurement.

### RJ Metric—Unweighted Root-Sum-Square (RMS) Sigma Calculation (Claim 13)

The unweighted RMS sigma (σᵣₘₛ) is defined as the root mean square of the combined variances without mixing weights. The unweighted RMS sigma is computed as:

$${σ}_{rms} = \sqrt{\sum {σ}_{i}^{2}}$$

Such implement in the unweighted RMS sigma is to compare the reference standard deviation σ_{ref}) of the hlane in the level histogram that each component represents an independent jitter or noise source rather than probabilistic modes. For an absolute RJ measurement, this additive-noise model guarantees that σᵣₘₛ>σ_{ref}, providing an absolute and conservative metric for increases in RMS jitter when multiple independent mechanisms are combined. It avoids the potential narrowing effect seen in weighted RMS sigma calculations when relying on probabilistic weights.

### RJ Metric—Delta RMS Sigma Calculation (Claim 14)

The delta RMS sigma (Δσ) is to quantify the increase in unweighted RMS sigma σᵣₘₛ beyond a reference standard deviation σ_{ref} of the hlane, the method calculates Δσ by:

Δσ=σᵣₘₛ−σ_{ref}

This metric highlights the excess noise introduced beyond the reference region.

### Total Jitter Variance Calculation (Claim 15)

The variance-based Total jitter (TJ) is computed as the sum of variance-based deterministic and random jitter variances:

TJ=DJ+RJ

This cumulative value provides a comprehensive measure of the variance-based jitter of a level histogram within the 1UI PAM-n Pattern.

1. A method comprising steps for:
importing a photo or a digital file of a multi-level Pulse Amplitude Modulation (PAM-n) eye diagram captured from a digital sampling oscilloscope;
editing the PAM-n eye diagram from a configuration with 2UI (unit interval) or multiple UI to a 1UI PAM-n pattern using image processing techniques;
grouping a mixture of transition lanes into level groups and configuring a jitter testing sequence;
acquiring a horizontal lane (hlane) histogram from the midpoint region of a level group, and acquiring a level histogram, defined as a mixture of transition lanes, from a region near the end of the level;
fitting a Gaussian distribution to the hlane histogram to establish a reference mean (ref mean) and standard deviation (ref sigma) for absolute jitter measurement;
applying a Gaussian Mixture Model (GMM) with Expectation-Maximization (EM) algorithm to decompose the level histogram or dataset and extract GMM component parameters;
calculating the grand mean and variance-based deterministic jitter (DJ) for the level histogram using a Finite Mixture Model (FMM), along with associated metric parameters relative to the reference mean, including the grand mean shift, DJ mean shift, and absolute DJ mean;
calculating the variance-based random jitter (RJ) and the weighted RJ sigma for the level histogram using a FMM, along with associated metric parameters relative to the reference standard deviation, including the unweighted root mean square (RMS) sigma and the delta RMS sigma;
calculating variance-based total jitter (TJ) by summing variance-based deterministic jitter (DJ) and random jitter (RJ);
visualizing and reporting the GMM component parameters, RJ, DJ, TJ, and associated jitter metric parameters.

2. The method of claim 1, wherein editing the PAM-n eye diagram to the 1UI PAM-n pattern comprises:
selecting two sampling points, (x₁, y₁) and (x₂, y₂), along a horizontal line of the PAM-n eye diagram, wherein both points exhibit the same local pattern and x₁<x₂;
selecting a third sampling point, (x₃, y₃), located at the center of the eye in the PAM-n eye diagram, such that x₁<x₃<x₂;
converting a color image of the PAM-n eye diagram into a grayscale image using image processing techniques;
vertically cropping the grayscale image into two segments: a first segment (img₁) extending from x₁ to x₃, and a second segment (img₂) extending from x₃ to x₂;
recombining the two segments in reverse order by placing img₂ before img₁, thereby generating a 1UI PAM-n pattern image (img₃).

3. The method of claim 1, wherein grouping transition lanes into level groups and configuring a jitter testing sequence comprises:
identifying distinct level groups at the end of the 1UI PAM-n pattern based on their corresponding levels;
identifying each transition lane by its Start and End states, denoted as (Start, End);
grouping a mixture of lanes along the amplitude axis to form n distinct level groups within the PAM-n pattern;
ensuring that each level group comprises one horizontal lane (hlane) and n−1 inter-level transition lanes, grouped based on a shared Start or End state;
configuring a sequence for jitter testing by selecting either a top-to-bottom or bottom-to-top order, and testing the middle-level groups in the 1UI PAM-n pattern.

4. The method of claim 1, wherein acquiring hlane histograms and a level histogram from a level group comprises:
selecting a sampling point for the hlane signal at the midpoint of the level within a 1UI PAM-n pattern;
setting a pixel intensity threshold near the hlane signal region where multiple transition lanes overlap;
acquiring an overall pixel intensities of the signals along the vertical axis at the selected hlane sampling point;
calculating the hlane histogram by subtracting the pixel intensity threshold from the overall signal intensities;
selecting a sampling point for the level signal near an end of the level region;
acquiring a level histogram by collecting pixel intensities along the vertical axis at the selected level sampling point.

5. The method of claim 1, wherein applying a Gaussian Mixture Model (GMM) with an Expectation-Maximization (EM) algorithm to decompose a level histogram or dataset and extract GMM parameters comprises:
evaluating the Akaike Information Criterion (AIC) and the Bayesian Information Criterion (BIC) as mode selection tools across varying numbers of distribution components in the decomposition of the level histogram;
selecting an optimal number of components at which both the AIC and BIC values fall within a predefined proximity of their respective minimums;
applying the EM algorithm within the GMM framework to fit the level histogram using the selected number of components;
extracting, for each component, a set of decomposition parameters including a weight, a mean, and a standard deviation;
generating a probability density function (PDF) for each component and an aggregate PDF representing the sum of all components.

6. The method of claim 1, wherein calculating a grand mean comprises computing a weighted sum of the means of the Gaussian components of the level histogram, in accordance with a Finite Mixture Model (FMM) equation set forth in the specification.

7. The method of claim 1, wherein calculating a variance-based deterministic jitter (DJ) comprises computing a weighted sum of squared deviations of component means relative to the grand mean, in accordance with a FMM equation set forth in the specification.

8. The method of claim 1, wherein calculating a DJ metric parameter, grand mean shift, comprises computing the difference between the grand mean and the reference mean, in accordance with an equation set forth in the specification.

9. The method of claim 1, wherein calculating a DJ metric parameter, DJ mean shift, comprises computing the square root of the variance-based deterministic jitter (DJ), in accordance with an equation set forth in the specification.

10. The method of claim 1, wherein calculating a DJ metric parameter, absolute DJ mean, comprises computing the sum of the reference mean and the product of the sign of the grand mean shift and the DJ mean shift, in accordance with an equation set forth in the specification.

11. The method of claim 1, wherein calculating a variance-based random jitter (RJ) comprises computing the weighted sum of the variances of the Gaussian components of the level histogram, in accordance with a Finite Mixture Model (FMM) equation set forth in the specification.

12. The method of claim 1, wherein calculating an RJ metric parameter, weighted RJ sigma, comprises computing the square root of the variance-based random jitter (RJ), in accordance with an equation set forth in the specification.

13. The method of claim 1, wherein calculating an RJ metric parameter, unweighted root-sum-square sigma (unweighted RMS sigma), comprises computing the square root of the sum of the component variances, in accordance with an equation set forth in the specification.

14. The method of claim 1, wherein calculating an RJ metric parameter, delta RMS sigma (Δσ), comprises determining the difference between the unweighted RMS sigma and the reference standard deviation, in accordance with an equation set forth in the specification.

15. The method of claim 1, wherein calculating variance-based total jitter (TJ) comprises summing the variance-based deterministic jitter (DJ) and random jitter (RJ), each computed as described above, in accordance with an equation set forth in the specification.

16. The method of claim 1, wherein visualizing and reporting comprises generating graphical outputs and/or data tables that display the GMM decomposition results, variance-based DJ, RJ, TJ and all associated jitter metric parameters for one or more level groups.
